(19) United States
(12) Patent Application Publication
(10) Pub. No.: US 2005/0058235 A1
(43) Pub. Date: Mar. 17, 2005

(54) CLOCK AND DATA RECOVERY SYSTEM FOR A WIDE RANGE OF BIT RATES

(76) Inventors: David A. Beeson, Pleasanton, CA (US); Edward S.L. Chan, Fremont, CA (US)

Correspondence Address: INTELLECTUAL PROPERTY LAW OFFICE, 1901 S. BASCOM AVENUE, SUITE 660, CAMPBELL, CA, 95008, US

(21) Appl. No.: 10/605,929

(22) Filed: Nov. 6, 2003

Related U.S. Application Data
(60) Provisional application No. 60/481,391, filed on Sep. 17, 2003.

(51) Int. Cl. H03D 3/24

(52) U.S. Cl. 375/376

(57) ABSTRACT

A clock recovery system (10) for recovering an input data signal (14) clock. A rate detector (20) detects the input data signal bit rate and provides range signals (30a-c) specifying progressive ranges encompassing the bit rate. A frequency detector (22) provides a frequency error signal (32) based on frequency difference between the input data signal and a recovered clock signal (16). A phase detector (24) provides a phase error signal (34) based on the input data and recovered clock signals. A filter-controller (26) provides an oscillator driving signal (36) based on the range, frequency error, and phase error signals. An oscillator-divider (28) then provides the recovered clock signal based on the oscillator driving signal and at least some of the range signals. The phase detector, filter-controller, and oscillator-divider collectively thus form a phase locked loop. Optionally, the clock recovery system (10) may also provide a recovered data signal (18).

### CROSS REFERENCE TO RELATED APPLICATIONS

This application claims the benefit of U.S. Provisional Application No. 60/481,391, filed Sep. 17, 2003.

### BACKGROUND OF INVENTION

1. Technical Field

The present invention in general relates to optical data transmission systems, and in particular to devices and methods for recovering the timing information and data after an optical signal has been converted to an electronic signal.

2. Background Art

Clock and data recovery (CDR) have long been performed on serial data transmissions to recover the timing information and the data at the receiving end of a serial line. Clock recovery for electrical wire line standards has unique conditioning standards that vary with the clock frequency. This results in the clock frequency or bit rate being known and being constant for the CDR devices used there. With the advent of optical communications methods, however, the large bandwidth and low loss of the fiber optic systems used has no inherent limitation that the bit rate be constant.

The present techniques for performing the CDR function all require that the data rate be known prior to clock recovery. Almost all present CDR devices therefore operate at a single data rate which is fixed at the time of design. The few devices claiming multi-rate capability require configuration or reference clocks of a particular frequency that is harmonically related to the target bit rate. These latter devices would be more accurately termed as “configurable,” rather than multi-rate, since the feature requires external assistance to transition to another bit rate capability.

While this presents no impediment to wire line communications, since the multitude of signaling standards there require unique interfaces anyway, it represents a significant barrier to bit rate transparency in serial optical communications. Optical communication systems can adopt various protocols, such as FDDI (Fiber Distributed Data Interface), ESCON (Enterprise Systems Connectivity), Fiber Channel, Gigabit Ethernet, and ATM (Asynchronous Transfer Mode) for high-bandwidth and high-bit-rate communications. The fiber optics technology used can also adopt various bit rates of 125 Mb/s, 155 Mb/s, 200 Mb/s, 622 Mb/s, 1062 Mb/s, 1.25 Gb/s, and 2.5 Gb/s to supply the capacity to meet the demand for multimedia applications. The use of forward error correction (FEC) also produces various other bit rates as additional coding bits are added to increase data integrity without decreasing the payload.

Optical communication systems are currently constrained by the electrical devices at their terminations to only carry data at the data rate which a CDR device is prepared to receive. It follows that it is highly desirable to remove this constraint. This will afford greater flexibility and improve efficiency. Repeater functions would also no longer need to be locked to a specific bit rate, thus easing the reconfiguration of networks. In sum, most aspects of optical switching would then be easier to implement, since fibers would not have to be limited by the optical to electrical (O/E) interface.

### SUMMARY OF INVENTION

Accordingly, it is an object of the present invention to provide an improved clock and data recovery system.

Briefly, one preferred embodiment of the present invention is a system for recovering the clock from an input data signal. A rate detector detects a bit rate of the input data signal and provides multiple range signals specifying progressively high to low ranges encompassing the bit rate. A frequency detector provides a frequency error signal based on the difference in frequency between the input data signal and a recovered clock signal. A phase detector provides a phase error signal based on the input data signal and the recovered clock signal. A filter-controller provides an oscillator driving signal based on the range signals, the frequency error signal, and the phase error signal. An oscillator-divider then provides the recovered clock signal based on the oscillator driving signal and at least some of the range signals. The phase detector, the filter-controller, and the oscillator-divider thus collectively form a phase locked loop.

An advantage of the present invention is that it permits bit rate transparency in serial optical communications.

Another advantage of the invention is that it is not necessarily limited to one fixed bit rate or to a few externally configurable fixed bit rates.

Another advantage of the invention is that it is that it does not require that the data rate be known and constant prior to clock recovery.

And another advantage of the invention is it is easily and efficiently employable in existing and emerging optical communication systems using a wide variety of protocols and error correction techniques.

These and other objects and advantages of the present invention will become clear to those skilled in the art in view of the description of the best presently known mode of carrying out the invention and the industrial applicability of the preferred embodiment as described herein and as illustrated in the several figures of the drawings.

### BRIEF DESCRIPTION OF DRAWINGS

The purposes and advantages of the present invention will be apparent from the following detailed description in conjunction with the appended figures of drawings in which:

FIG. 1 is a block diagram depicting an overview of a clock and data recovery circuit (CDR circuit) in accord with the present invention.

FIG. 2 is a block diagram depicting a suitable embodiment of the rate detector of FIG. 1.

FIG. 3A-C are block diagrams depicting suitable embodiments of the three rate range units of the rate detector in FIG. 2.

FIG. 4 is a block diagram depicting a suitable embodiment of the frequency detector of FIG. 1.

FIG. 5 is a block diagram depicting a suitable embodiment of the phase detector of FIG. 1.

FIG. 6 is a block diagram depicting an analog embodiment of the filter-controller.

FIG. 7 is a block diagram depicting a digital embodiment of the filter-controller.

FIG. 8 is a block diagram depicting a suitable embodiment of the oscillator-divider of FIG. 1.

FIG. 9 is a block diagram depicting application of the CDR circuit in a receiver.

And FIG. 10 is a block diagram depicting application of the CDR circuit in a transceiver.

In the various figures of the drawings, like references are used to denote like or similar elements or steps.

### DETAILED DESCRIPTION

### BEST MODE FOR CARRYING OUT THE INVENTION

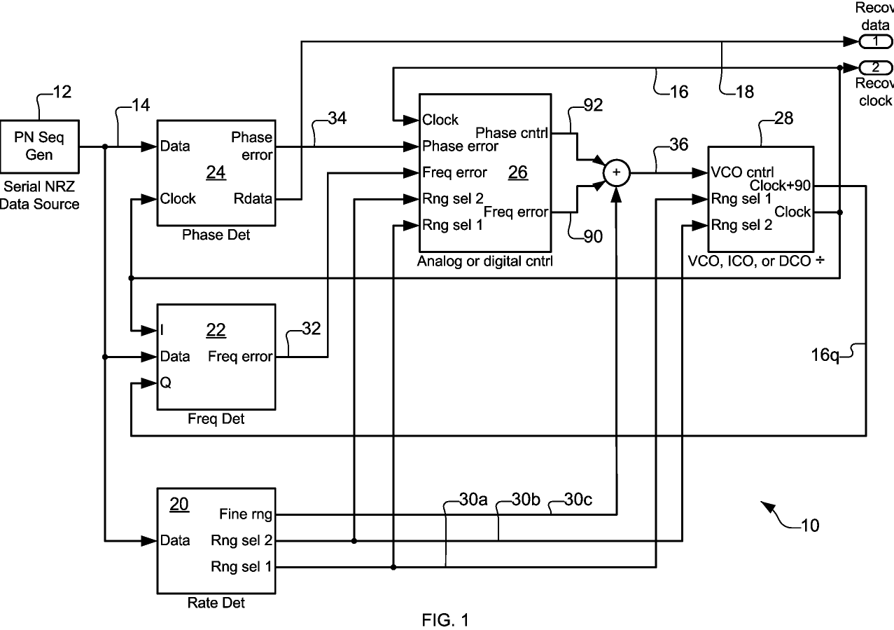

A preferred embodiment of the present invention is a clock and data recovery system suitable for use with a wide range of bit rates. As illustrated in the various drawings herein, and particularly in the view of FIG. 1, preferred embodiments of the invention are depicted by the general reference character 10.

FIG. 1 is a block diagram depicting an overview of a clock and data recovery circuit (CDR circuit 10) in accord with the present invention. The CDR circuit 10 works with a serial data source 12 that provides a source data signal 14, to ultimately obtain a recovered clock signal 16 and a recovered data signal 18. For this, the major components of the CDR circuit 10 include a rate detector 20, a frequency detector 22, a phase detector 24, a filter-controller 26, and an oscillator-divider 28.

Respectively, the rate detector 20, frequency detector 22, and phase detector 24 serve as first through third measurement sub-circuits. The task of the rate detector 20, as the first measurement sub-circuit, is to make a coarse determination of the bit rate in the source data signal 14 by measuring the transition density. Based on this, the rate detector 20 provides control signals to the filter-controller 26 and the oscillator-divider 28. In the embodiment in FIG. 1, the rate detector 20 provides three range select signals 30a-c. With these the filter-controller 26 and oscillator-divider 28 are able produce the recovered clock signal 16 as a coarse approximation.

Once coarse setting of the recovered clock signal 16 is complete, the frequency detector 22, as the second measurement sub-circuit, becomes the primary effect on the frequency of the recovered clock signal 16 by adjusting it more finely to match the clock of the source data signal 14. This is done by measuring the direction of any residual frequency offset and providing a frequency error signal 32 to the filter-controller 26, to adjust the output frequency of the recovered clock signal 16 in a compensating manner. The size of the adjustment is chosen to ensure the entry of the frequency of the recovered clock signal 16 into the useful range of the third sub-circuit.

Next, the phase detector 24, as the third measurement sub-circuit, reduces the average phase error to zero and holds the phase of the recovered clock signal 16 locked to the data in the source data signal 14. This is done in the characteristic manner of a phase locked loop (PLL), wherein the phase detector 24, filter-controller 26, and oscillator-divider 28 act as a PLL detector, PLL loop filter and PLL controllable oscillator. The phase detector 24 provides a phase error signal 34 to the filter-controller 26, the filter-controller 26 contributes to an oscillator driving signal 36 that is provided to the oscillator-divider 28, and the oscillator-divider 28 provides the recovered clock signal 16 (as well as a shifted clock signal 16q that is phased-shifted 90 degrees in the particular embodiment shown). The recovered clock signal 16 is fed back to the phase detector 24, thus completing the PLL. Once the PLL locks in, the recovered clock signal 16 from the oscillator-divider 28 is accurate and further obtaining the recovered data signal 18 is straightforward.

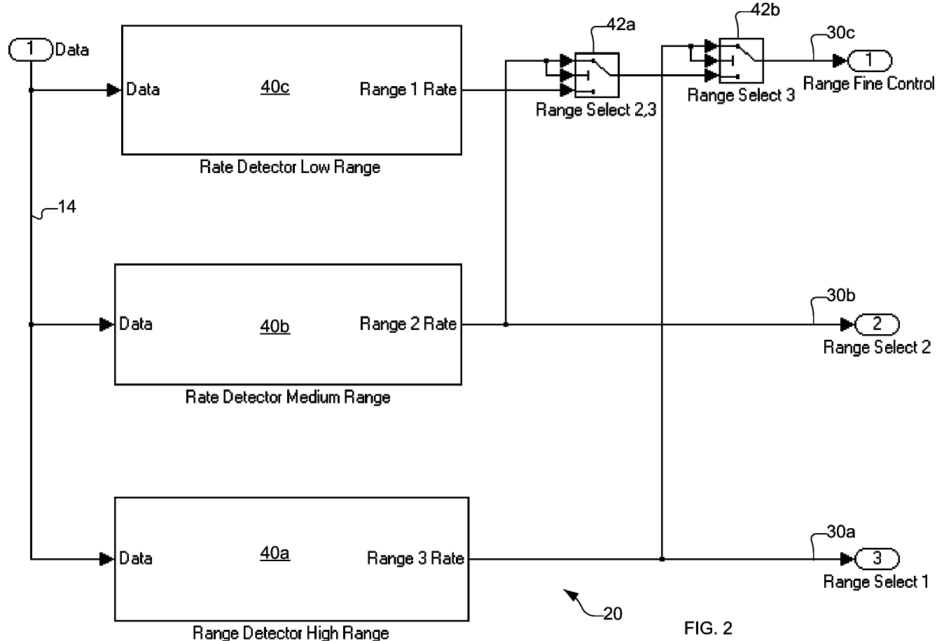

FIG. 2 is a block diagram depicting a suitable embodiment of the rate detector 20, i.e. the first measurement sub-circuit. Again, the task of the rate detector 20 is to bring the recovered clock signal 16 into a coarse match with the source data signal 14. In this embodiment, three parallel rate range units 40a-c are used with appropriate switches 42a-b to route the three range select signals 30a-c to the filter-controller 26 and oscillator-divider 28. The switches 42a-b in the embodiment shown operate based on the voltage levels. Thus, switch 42b will pass the high range select signal 30a until the voltage of this signal drops sufficiently, indicating that the medium or low range is now usable. Similarly, switch 42a will pass the medium range select signal 30b until the voltage of this signal drops sufficiently, indicating that the low range is now usable.

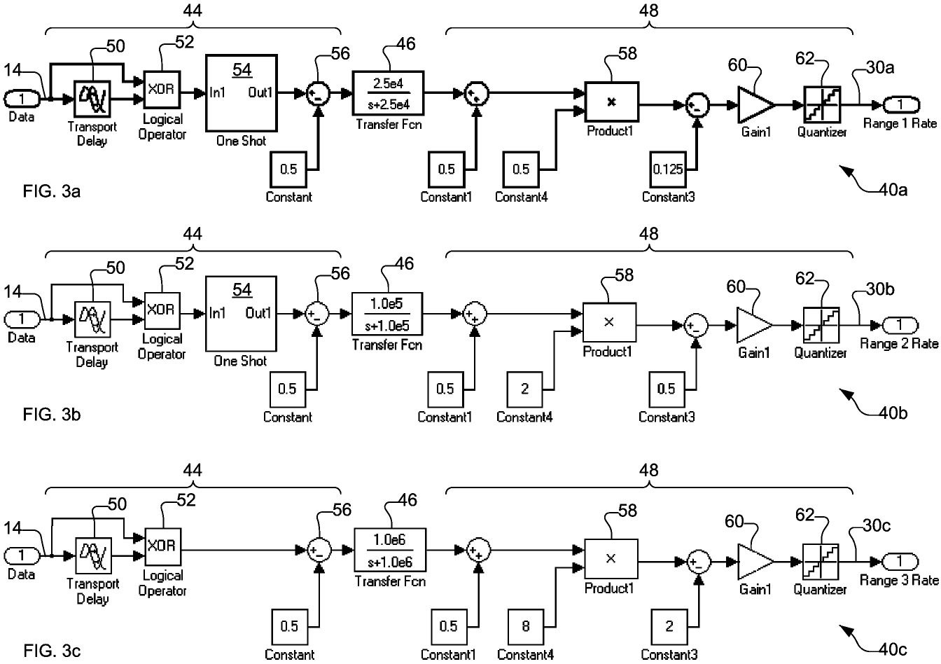

FIG. 3A-C are block diagrams depicting suitable embodiments of the three rate range units 40a-c of the rate detector 20 in FIG. 2. As these differ only in component values, we describe only the first rate range unit 40a for brevity. Each rate range unit includes input tailoring circuitry 44, a filter 46, and output tailoring circuitry 48. The input tailoring circuitry 44 converts data pulses from the source data signal 14 to uniform width pulses. The input tailoring circuitry 44 in this embodiment includes a transport delay 50, an XOR logical operator 52, a one-shot unit 54 (the low rate range unit 40c does not require a one-shot unit to avoid aliasing, since the pulses there are narrow enough already), and a summing unit 56 that applies an edge probability of 0.5 for efficient pulse handling, elimination of noise, etc. Next, the filter 46 converts the pulses into a level signal (i.e., a voltage or current). The transition density is thus averaged over the period of time required by the lowest desired bit rate to settle within the frequency range of the succeeding measurement. The output tailoring circuitry 48 then tailors the level signal to drive later components. The output tailoring circuitry 48 includes level shift sub-circuitry 58, a buffer 60, and a quantitizer 62 that quantitizes the signal into the respective range select signal that leaves the rate detector 20.

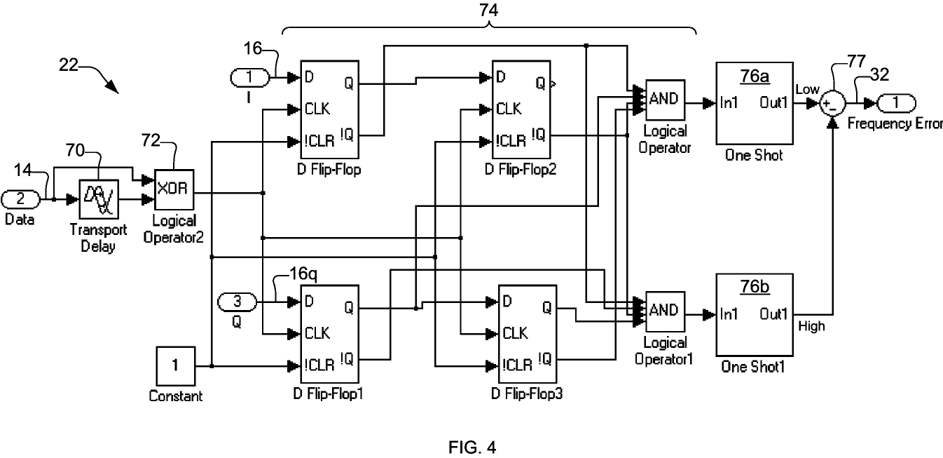

FIG. 4 is a block diagram depicting a suitable embodiment of the frequency detector 22 of FIG. 1. Recall, the task of the frequency detector 22 is to bring the recovered clock signal 16 into a frequency match with the source data signal 14. The frequency detector 22 also includes a transport delay 70 and an XOR logical operator 72. These also convert data pulses from the source data signal 14 to uniform width pulses (input tailoring), which then are processed with the recovered clock signal 16 and the shifted clock signal 16q by a matching circuit 74, two one-shot units 76a-b, and a summing unit 77 to obtain the frequency error signal 32. The matching circuit 74 used in this embodiment is essentially a conventional circuit constructed of flip-flops and AND gates that determines what quadrant an edge of the source data signal 14 is in relative to the recovered clock signal 16.

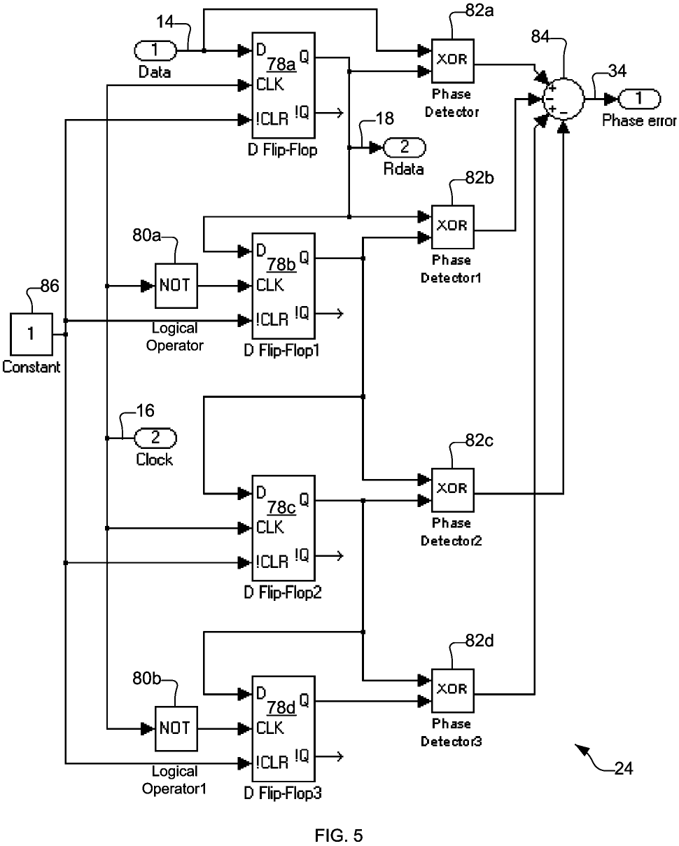

FIG. 5 is a block diagram depicting a suitable embodiment of the phase detector 24 of FIG. 1. The phase detector 24 is the third measurement circuit and it reduces the average phase error to zero and holds the clock phase locked to the data. The phase detector 24 may also be an essentially conventional circuit, here it includes a chain of four flip-flops 78a-d. The first flip-flop 78a (starting the chain) receives the source data signal 14. The first and second flip-flops 78a, 78c receive the recovered clock signal 16 while the third and fourth flip-flops 78b, 78d are preceded by NOT logical operators 80a-b that invert the recovered clock signal 16. Four XOR logical operators 82a-d are used as phase sub-detectors to compare the outputs of the flip-flops 78a-d, with their results processed by a summing unit 84 to provides the phase error signal 34. Once the phase detector 24 locks in (i.e., the PLL locks in), the output of the first flip-flop 78a is the recovered data signal 18. The phase detector 24 also includes a reset unit 86, to reset the flip-flops 78a-d on power up.

The filter-controller 26 may be implemented with either analog or digital control. Unlike a loop filter in a conventional PLL, which produces only a phase difference signal, the filter-controller 26 in the inventive CDR circuit 10 produces both a frequency control signal 90 and a phase control signal 92. These along with the third range select signal 30c (for the low range) are combined to produce the driving signal 36 (FIG. 1) used by the oscillator-divider 28. In FIG. 1 the summing of the third range select signal 30c, frequency control signal 90, and phase control signal 92 is shown taking place outside the filter-controller 26, since this is how the inventors currently implement preferred embodiments. Conceptually, however, this summing can be viewed as occurring inside the filter-controller 26. This helps view it more like a loop filter in a conventional PLL.

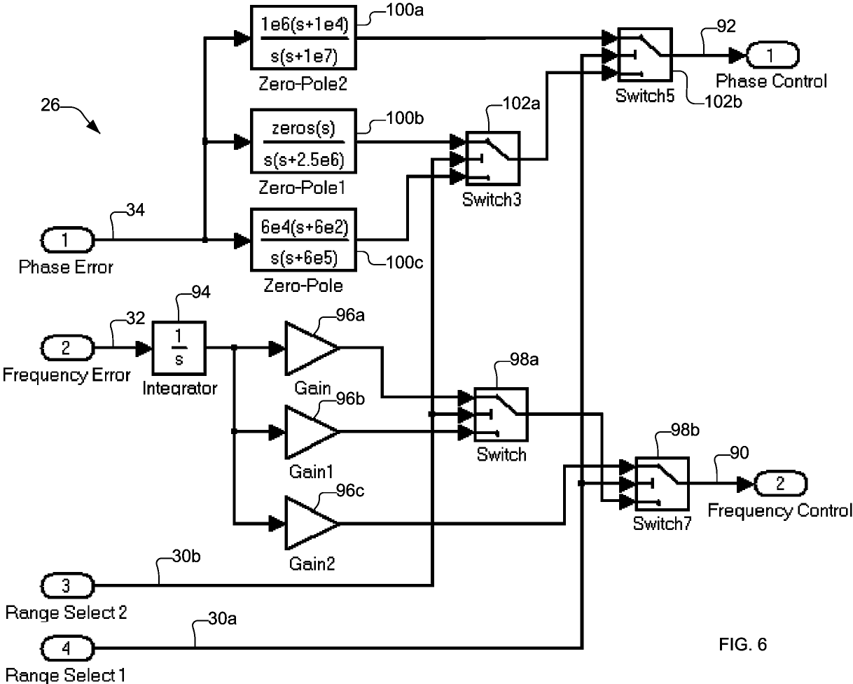

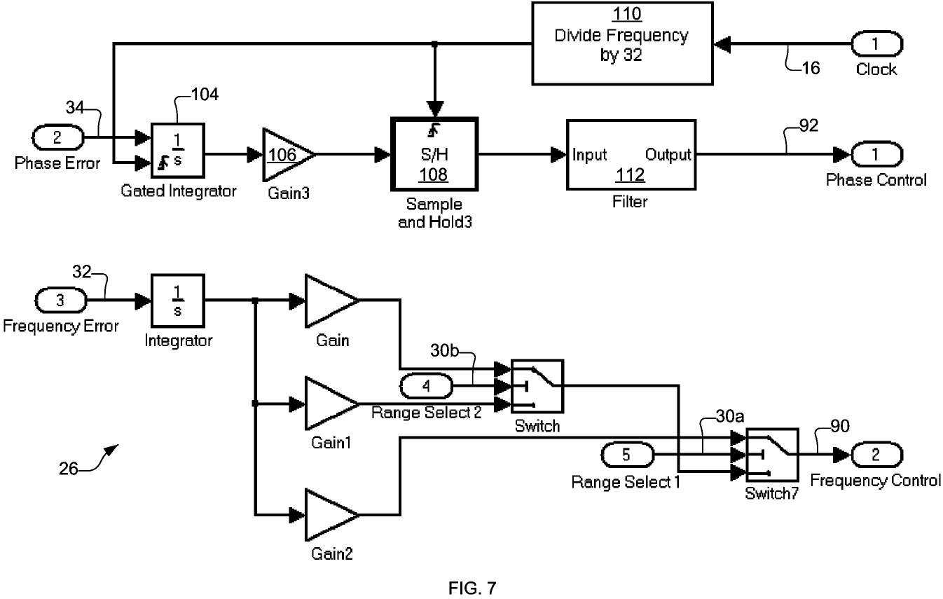

FIG. 6 is a block diagram depicting an analog embodiment of the filter-controller 26, and FIG. 7 is a block diagram depicting a digital embodiment of the filter-controller 26. From comparison of FIG. 6 and FIG. 7 it can be appreciated that processing the frequency error signal 32 into the frequency control signal 90 may be essentially the same when either analog or digital control is used. The frequency error signal 32 is integrated in an integrator 94, then amplified in amplifiers 96a-c, and the output of an amplifier is selected to be the frequency control signal 90 with switches 98a-b. FIG. 6 also depicts circuitry for processing the phase error signal 34 into the phase control signal 92 using analog control. The phase error signal 34 is processed by three zero pole filters 100a-c and the output of one filter is selected with switches 102a-b to be the phase control signal 92. In this embodiment the switches 98a-b and switches 102a-b operate based on voltage levels in high and medium range select signals 30a-b.

FIG. 7 depicts circuitry for processing the phase error signal 34 into the phase control signal 92 using digital control. The phase error signal 34 here is processed by a gated integrator 104, amplified by an amplifier 106, and further processed by a sample and hold unit 108. For this, the recovered clock signal 16 is divided in a divide-by-32 frequency divider 110 to provide a signal used to trigger the gated integrator 104 and the sample and hold unit 108. The output of the sample and hold unit 108 is then filtered with a filter 112 to become the phase control signal 92.

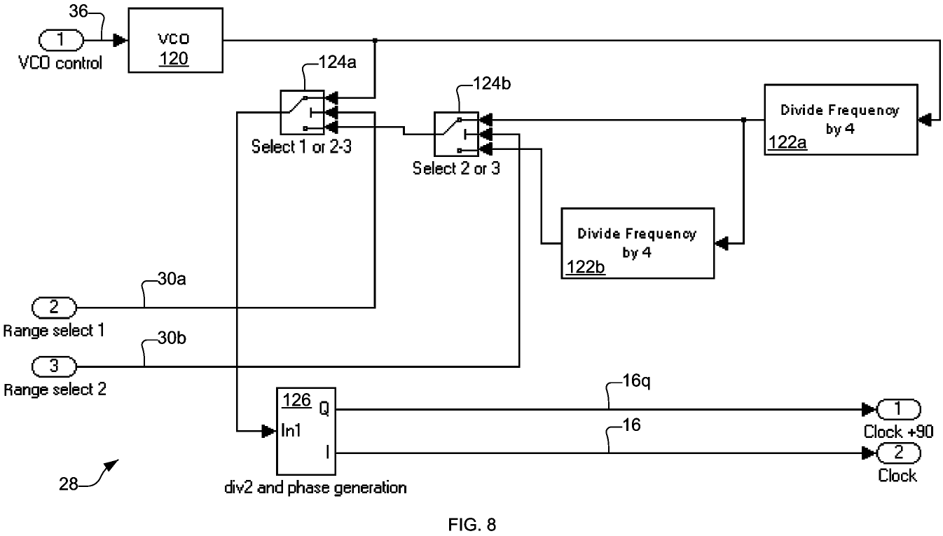

FIG. 8 is a block diagram depicting a suitable embodiment of the oscillator-divider 28 of FIG. 1. The oscillator-divider 28 here includes a voltage controlled oscillator (VCO 120)(alternate embodiments can use current or digitally controlled oscillators), two divide-by-4 frequency dividers 122a-b, switches 124a-b, and a divide-by-2 divider-phase generator 126. The driving signal 36 at this point is the sum of the low range select signal 30c, the frequency control signal 90, and the phase control signal 92. The driving signal 36 drives the VCO 120, in this embodiment at double the rate of the recovered clock signal 16 (and thus nominally at double the rate of the source data signal 14). The output of the VCO 120 is routed to the first switch 124a and the divide-by-4 frequency dividers 122a-b as shown.

If the voltage levels of the high and medium range select signals 30a-b indicate that the recovered clock signal 16 is not yet well matched with the source data signal 14, the switches 124a-b route the output of the VCO 120 after the two divide-by-4 frequency dividers 122a-b onward. If the voltage level of the medium range select signal 30b indicates that the recovered clock signal 16 is only roughly matched with the source data signal 14, switch 124a routes the output of the VCO 120 after only the first divide-by-4 frequency divider 122a onward. And if the voltage levels of the high and medium range select signals 30a-b indicate that the recovered clock signal 16 is fairly well matched with the source data signal 14, switch 124a routes the direct output of the VCO 120 onward. The divide-by-2 divider-phase generator 126 then receives the result of this switching. It divides what it receives by two, creating the both the recovered clock signal 16 and the shifted clock signal 16q. Accordingly, the 2×output of the VCO 120 is divided by 32 (4*4*2) to get the recovered clock signal 16 if the low range of the CDR circuit 10 is needed, divided by 8 (4*2) if the medium range is needed, and divided by 2 if only the high range is needed.

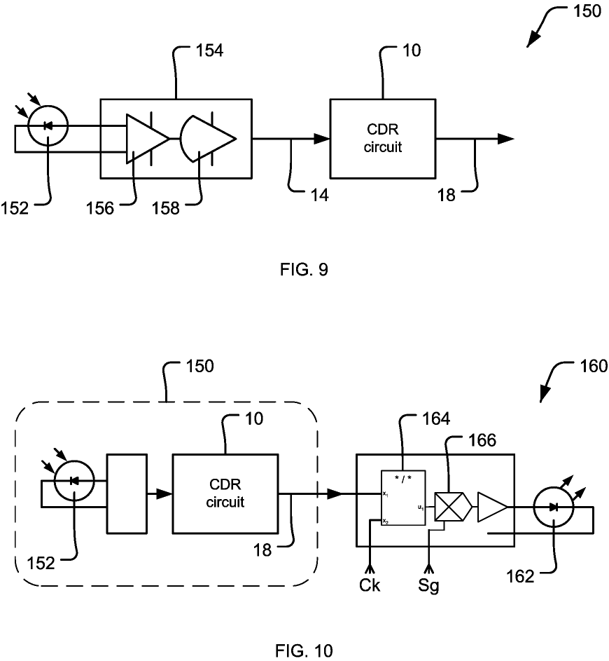

FIG. 9 is a block diagram depicting application of the CDR circuit 10 in a receiver 150. As before, the CDR circuit 10 provides the recovered data signal 18 based on the source data signal 14, but the data source 12 is now shown in more detail. In its most basic form, the data source 12 is photodiode 152 that converts data in optical form to the electrical form of the source data signal 14. In most cases, however, conditioning circuitry 154 will also be provided to make tailor the source data signal 14 before it is provided to the CDR circuit 10. Without limitation, such conditioning circuitry 154 may include a trans-impedance amplifier 156 and a post amplifier 158.

FIG. 10 is a block diagram depicting application of the receiver 150, with the CDR circuit 10, in a transceiver 160. In most basic form here, the recovered data signal 18 from the CDR circuit 10 is provided directly to a photodiode 162 that converts the recovered data signal 18 from electrical form to optical form. This simple arrangement might be used, for instance, to apply the transceiver 160 as a repeater. The transceiver 160 may also include a frequency converter 164. This arrangement can be used to change the recovered data signal 18 to a clock rate, or to another protocol, other than that of the recovered clock signal 16. Another arrangement is to add a multiplexer 166, to combine one or more other data signals with the recovered data signal 18 before converting all with the photodiode 162.

While various embodiments have been described above, it should be understood that they have been presented by way of example only, and not limitation. Thus, the breadth and scope of the invention should not be limited by any of the above described exemplary embodiments, but should be defined only in accordance with the following claims and their equivalents.

### INDUSTRIAL APPLICABILITY

The present invention is well suited for application in a wide variety of communications systems, particularly including optical communications systems. As has been described elsewhere herein, optical communications systems have no inherent limitation that a bit rate used be constant. Accordingly, the optical communications industry is already using a variety of protocols, speeds, and error correction techniques, and this can only be expected to grow. The CDR circuit 10, described herein as an exemplary embodiment of the invention, shows how the invention is very well suited to handle the CDR function when a bit rate is not known prior to clock recovery or when it changes somewhat over time or is intentionally changed.

This overcomes sever limitations in the prior art. The prior approaches to clock and data recovery are generally limited to when a bit rate is known and constant prior to clock recovery. These prior approaches accordingly are able to handle only one bit rate, set at design time, or a few selectable bit rates, also set at design time and requiring external assistance to make a particular selection.

While not to shadow its potential applicability also in electrical “wire line” communications, the present invention overcomes the major limitations in the prior art that have limited its utility in optical communication systems. This invention affords greater flexibility and improve efficiency in such communications. For instance, repeater functions no longer need to be locked to a specific bit rate, thus easing the reconfiguration of networks. And generally, use of this invention permits most aspects of optical switching to be easier to implement, since fiber optical systems need not be limited by the optical to electrical (O/E) interface.

For the above, and other, reasons, it is expected that the present invention will have widespread industrial applicability and it is expected that the commercial utility of the invention will be extensive and long lasting.

1. A system for recovering the clock from an input data signal, comprising:
a rate detector for detecting a bit rate of the input data signal and providing a plurality of range signals specifying progressively high to low ranges encompassing said bit rate;
a frequency detector for providing a frequency error signal based on a difference in frequencies between the input data signal and a recovered clock signal;
a phase detector for providing a phase error signal based on the input data signal and said recovered clock signal;
a filter-controller for providing an oscillator driving signal based on said plurality of range signals, said frequency error signal, and said phase error signal; and
an oscillator-divider for providing said recovered clock signal based on said oscillator driving signal and at least some of said plurality of range signals; and wherein:
said phase detector, said filter-controller, and said oscillator-divider collectively form a phase locked loop.

2. The system according to claim 1, wherein said rate detector includes a plurality of range sub-circuits each providing one of said plurality of range signals.

3. The system according to claim 2, wherein said range sub-circuits include an input tailoring circuit for tailoring the input data signal, a filter for filtering the tailored input data signal, and an output tailoring circuit for tailoring the filtered input data signal into a respective said range signal.

4. The system according to claim 1, wherein said phase detector further produces a recovered data signal based on the input data signal, thereby making the system suitable for use as a clock and data recovery circuit.

5. The system according to claim 1, wherein said filter-controller includes:
an integrator for integrating said frequency error signal;
a plurality of amplifiers for amplifying the integrated said frequency error signal into a plurality of amplified said frequency error signals equaling said ranges in quantity; and
a switch for controllably selecting one amplified said frequency error signal to contribute to said oscillator driving signal.

6. The system according to claim 1, wherein said filter-controller includes:
a plurality of analog filters for filtering said phase error signal into a plurality of filtered said phase error signals equaling said ranges in quantity; and
a switch for controllably selecting one of said plurality of the filtered said phase error signals to contribute to said oscillator driving signal.

7. The system according to claim 1, wherein said filter-controller includes:
a gated integrator for integrating said phase error signal;
a gated sample and hold circuit for sampling the integrated said phase error signal;
a frequency divider for dividing the frequency of said recovered clock signal, wherein the divided said recovered clock signal gates said gated integrator and said gated sample and hold circuit; and
a digital filter for filtering the sampled said phase error signal to contribute to said oscillator driving signal.

8. The system according to claim 1, wherein said oscillator-divider includes:
a controllable oscillator producing an oscillating signal based on said oscillator driving signal; and
at least one frequency divider for dividing the frequency of said oscillating signal;
a switch for controllably selecting one from among said oscillating signal and the divided instances of said oscillating signal to contribute to said recovered clock signal.

9. The system according to claim 8, wherein said controllable oscillator is a member of the set consisting of voltage controlled oscillators, current controlled oscillators, and digitally controlled oscillators.

10. The clock and data recovery circuit according to claim 4 embodied in a receiver, wherein said receiver further comprises a photo diode for converting the input data signal from an optical form to an electrical form and providing it to the clock and data recovery circuit.

11. The receiver according to claim 10, wherein said receiver further comprises conditioning circuitry for conditioning said electrical form of the input data signal prior to providing it to the clock and data recovery circuit.

12. The receiver according to claim 11, wherein said signal conditioning circuitry includes a trans-impedance amplifier and a post amplifier.

13. The receiver according to claim 10 embodied in a transceiver, wherein said transceiver further comprises a laser diode for converting said recovered data signal into an optical output data signal.

14. The transceiver according to claim 13, wherein said transceiver further includes a frequency change circuit for converting said recovered data signal based on a clock other than said recovered clock signal.

15. The transceiver according to claim 13, wherein said transceiver further includes a multiplexer for combining said recovered data signal and at least one other data signal into said optical output data signal.

16. A method for recovering the clock from an input data signal, the method comprising the steps:
(a) detecting a bit rate of the input data signal and based thereon providing a plurality of range signals specifying progressively high to low ranges encompassing said bit rate;
(b) detecting a frequency error signal based on a difference in frequencies between the input data signal and a recovered clock signal;
(c) detecting a phase error signal based on the input data signal and said recovered clock signal;
(d) providing an oscillator driving signal based on said plurality of range signals, said frequency error signal, and said phase error signal; and
(e) providing said recovered clock signal based on said oscillator driving signal and at least some of said plurality of range signals, thereby using said phase error signal, said oscillator driving signal, and said recovered clock signal in the manner of a phase locked loop.

17. The method according to claim 16, wherein said step (a) includes:
(1) tailoring the input data signal;
(2) filtering the tailored input data signal; and
(3) tailoring the filtered input data signal into a respective said range signal.

18. The method according to claim 16, wherein said step (c) includes producing a recovered data signal based on the input data signal, thereby making the method suitable for use in both clock and data recovery.

19. The method according to claim 16, wherein said step (d) includes:
(1) integrating said frequency error signal;
(2) amplifying the integrated said frequency error signal into a plurality of amplified said frequency error signals equaling said ranges in quantity; and
(3) controllably selecting one amplified said frequency error signal to contribute to said oscillator driving signal.

20. The method according to claim 16, wherein said step (d) includes:
(1) filtering said phase error signal into a plurality of filtered said phase error signals equaling said ranges in quantity; and
(2) controllably selecting one of said plurality of the filtered said phase error signals to contribute to said oscillator driving signal.

21. The method according to claim 16, wherein said step (d) includes:
(1) integrating said phase error signal;
(2) sampling the integrated said phase error signal;
(3) dividing the frequency of said recovered clock signal, wherein the divided said recovered clock signal gates said step (1) and said step (2); and
(4) filtering the sampled said phase error signal to contribute to said oscillator driving signal.

22. The method according to claim 16, wherein said step (3) includes:
(1) producing an oscillating signal based on said oscillator driving signal;
(2) dividing the frequency of said oscillating signal at least once; and
(3) controllably selecting one from among said oscillating signal and the divided instances of said oscillating signal to contribute to said recovered clock signal.

23. The method according to claim 18, further comprising converting the input data signal from an optical form to an electrical form before further using it.

24. The method according to claim 23, further comprising conditioning said electrical form of the input data signal before further using it.

25. The method according to claim 23, further comprising converting said recovered data signal into an optical output data signal.

26. The method according to claim 25, further comprising converting the frequency of said recovered data signal based on a clock other than said recovered clock signal.

27. The method according to claim 25, further comprising multiplexing said recovered data signal and at least one other data signal into said optical output data signal.
